(19) United States
(12) Patent Application Publication
(10) Pub. No.: US 2018/0337165 A1
(43) Pub. Date: Nov. 22, 2018

(54) OPTICAL MODULE, DETECTING APPARATUS

(71) Applicant: SUMITOMO ELECTRIC INDUSTRIES, LTD., Osaka (JP)

(72) Inventor: Masaki MIGITA, Osaka (JP)

(73) Assignee: SUMITOMO ELECTRIC INDUSTRIES, LTD., Osaka (JP)

(21) Appl. No.: 15/979,189

(22) Filed: May 14, 2018

(30) Foreign Application Priority Data
May 17, 2017 (JP) 2017-098174

(51) Int. Cl. H01L 25/16; H01L 33/50; H01L 33/48; H01L 33/58; H01L 31/101

(52) U.S. Cl. CPC H01L 25/167; H01L 33/50; H01L 31/1013; H01L 33/58; H01L 33/486

(57) ABSTRACT

An optical module includes: a light emitting semiconductor device producing light in a middle and long wavelength infrared range; a photodetector sensitive to middle and long wavelength infrared light; and a container including a supporting member and a package. The supporting member has a first area and a second area different from the first area. The package has an optical window transmissive to middle and long wavelength infrared light; the light emitting semiconductor device is disposed on the first area; the photodetector is disposed on the second area; and the package supports the supporting member so as to allow the light emitting semiconductor device to emit the light to the optical window and allow the photodetector to receive light through the optical window.

### BACKGROUND OF THE INVENTION

### Field of the Invention

The present invention relates to an optical apparatus, and a stub device. This application claims the benefit of priority from Japanese Patent Application No. 2017-098174 filed on May 17, 2017, which is herein incorporated by reference in its entirety.

### Related Background Art

Japanese Patent Application Laid-Open Publication No.

2012-225730 (referred to as “Patent Document 1”) discloses an apparatus for measuring a concentration of gas. Japanese Patent Application Laid-Open Publication No. 2016-061754 (referred to as “Patent Document 2”) discloses a gas analyzing apparatus.

### SUMMARY OF THE INVENTION

An optical module according to one aspect of the present invention includes: a light emitting semiconductor device producing light in a middle and long wavelength infrared range; a photodetector sensitive to middle and long wavelength infrared light; and a container including a supporting member and a package, the supporting member having a first area and a second area different from the first area, the package including an optical window transmissive to middle and long wavelength infrared light, the light emitting semiconductor device being disposed on the first area, the photodetector being disposed on the second area, and the package supporting the supporting member so as to allow the light emitting semiconductor device to emit the light to the optical window and allow the photodetector to receive light through the optical window.

A detecting apparatus according to another aspect of the present invention includes: an optical module including; a light emitting semiconductor device producing light in a middle and long wavelength infrared range; a photodetector sensitive to middle and long wavelength infrared light; and a container including a supporting member and a package, the supporting member having a first area and a second area different from the first area, the package including an optical window transmissive to middle and long wavelength infrared light, the light emitting semiconductor device being disposed on the first area, the photodetector being disposed on the second area, and the package supporting the supporting member so as to allow the light emitting semiconductor device to emit the light to the optical window and allow the photodetector to receive light through the optical window; a holder including a holding portion holding the optical module; and a reflecting member being supported by the holder apart from the supporting member, the reflecting member reflecting the light from the light emitting semiconductor device.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIG. 1 is a schematic view showing a detecting apparatus including an optical module according to the present embodiment.

FIG. 2 is a schematic view showing a detecting apparatus according to Example 1.

FIG. 3 is a schematic view showing a detecting apparatus according to Example 2.

FIG. 4 is a schematic view showing a detecting apparatus according to Example 3.

FIG. 5A is a schematic view showing a major step in a method for fabricating an optical module according to the present embodiment.

FIG. 5B is a schematic view showing a major step in the method according to the present embodiment.

FIG. 5C is a schematic view showing a major step in the method according to the present embodiment.

FIG. 5D is a schematic view showing a major step in the method according to the present embodiment.

FIG. 6 is a schematic view showing a major step in the method according to the present embodiment.

### DESCRIPTION OF THE EMBODIMENTS

The gas concentration measurement apparatus in Patent Document 1 includes a light source and a detector, which are arranged on an axis. A flow channel providing a target gas flow is positioned to an optical path from the light source to the detector. The light source emits light, and the light propagates straight toward the detector across the flow channel.

The gas analyzing apparatus in Patent Document 2 includes a laser light source and a detector, and a flow channel providing a target gas flow is positioned to the optical path from the light source to the detector across the flow channel.

The apparatuses in Patent Documents 1 and 2 each have two packages, one of which contains the light source and the other of which contains the detector, optically-aligned with each other.

These packages are installed to the apparatus, and both the alignment and installation allow light from the light source to enter the detector. Each apparatus causes the light source and the detector to operate in the separate packages providing the light source and the detector with respective operating environments, which may be different from each other.

Embodiments according to the above aspects will be described below.

An optical module according to an embodiment includes: (a) a light emitting semiconductor device producing light in a middle and long wavelength infrared range; (b) a photodetector sensitive to middle and long wavelength infrared light; and (c) a container including a supporting member and a package, the supporting member having a first area and a second area different from the first area, the package including an optical window transmissive to middle and long wavelength infrared light, the light emitting semiconductor device being disposed on the first area, the photodetector being disposed on the second area, and the package supporting the supporting member so as to allow the light emitting semiconductor device to emit the light to the optical window and allow the photodetector to receive light through the optical window.

The optical module arranges the photodetector and the light emitting semiconductor device in the single package so as to allow the light emitting semiconductor device to emit light toward the optical window and allow the photodetector to receive light from the optical window. The package supports the light emitting semiconductor device in the first area of the supporting member and supports the photodetector in the second area of the supporting member. The alignment of the optical module with the detecting apparatus makes both the photodetector and the light emitting semiconductor device optically aligned with the detecting apparatus. The single package containing both the photodetector and the light emitting semiconductor device therein allows the photodetector and the light emitting semiconductor device to operate in a common operating environment.

In the optical module according to an embodiment, the optical window includes at least one of Ge, ZnSe, ZnS, Si, CaF₂, BaF₂, sapphire, diamond, or chalcogenide glass.

The optical module is provided with the optical window including Ge, ZnSe, ZnS, Si, CaF₂, BaF₂, sapphire, diamond and/or chalcogenide glass, which are transmissive to light in a mid-wavelength or long-wavelength infrared region.

In the optical module according to an embodiment, the photodetector includes one of an HgCdTe device, a sensor device having an InAs/GaSb superlattice, and a thermopile device.

The optical module is provided with the HgCdTe device, the sensor device having the InAs/GaSb superlattice, and/or the thermopile device, and these devices can detect mid-wavelength infrared light or long-wavelength infrared light.

In the optical module according to an embodiment, the light emitting semiconductor device includes a quantum cascade laser.

The optical module provides the light emitting semiconductor device with the quantum cascade laser, which can generate light in mid-wavelength and long-wavelength infrared region.

The optical module according to an embodiment further includes a temperature controlling device mounting the photodetector and the light emitting semiconductor device, the package including a stein and a cap, the cap having the optical window, and the stein mounting the temperature controlling device.

The optical module is provided with the temperature controlling device, which can control a single operating environment common to the photodetector and the light emitting semiconductor device.

In the optical module according to an embodiment, the photodetector is supported by the supporting member to receive returning light from a reflection member outside of the optical module, and the reflection member reflects the light from the light emitting semiconductor device to produce returning light.

The optical module is provided with the photodetector, which is aligned with the light emitting semiconductor to receive light travelling from the light emitting semiconductor by way of the reflection member.

In the optical module according to an embodiment, the light emitting semiconductor device is supported by the supporting member to provide the photodetector with returning light from a reflection member outside of the optical module, and the reflection member reflects light from the light emitting semiconductor device to form returning light.

The optical module is provided with the light emitting semiconductor, which is aligned with the photodetector to allow light from the light emitting semiconductor to enter the photodetector by way of the reflection member.

An detecting apparatus according to an embodiment includes: (a) an optical module including; a light emitting semiconductor device producing light in a middle and long wavelength infrared range; (b) a photodetector sensitive to middle and long wavelength infrared light; and (c) a container including a supporting member and a package, the supporting member having a first area and a second area different from the first area, the package including an optical window transmissive to middle and long wavelength infrared light, the light emitting semiconductor device being disposed on the first area, the photodetector being disposed on the second area, and the package supporting the supporting member so as to allow the light emitting semiconductor device to emit the light to the optical window and allow the photodetector to receive light through the optical window; (d) a holder including a holding portion holding the optical module; and (e) a reflecting member being supported by the holder apart from the supporting member, the reflecting member reflecting the light from the light emitting semiconductor device.

The detecting apparatus provides the holder, which positions the optical module to allow the light emitting semiconductor device and the photodetector therein to be optically coupled to the reflecting member through the optical window.

The teachings of the present invention can be readily understood by considering the following detailed description with reference to the accompanying drawings shown as examples. Referring to the accompanying drawings, embodiments according to the optical module and the detecting apparatus will be illustrated below. When possible, the same portions will be denoted by the same reference numerals.

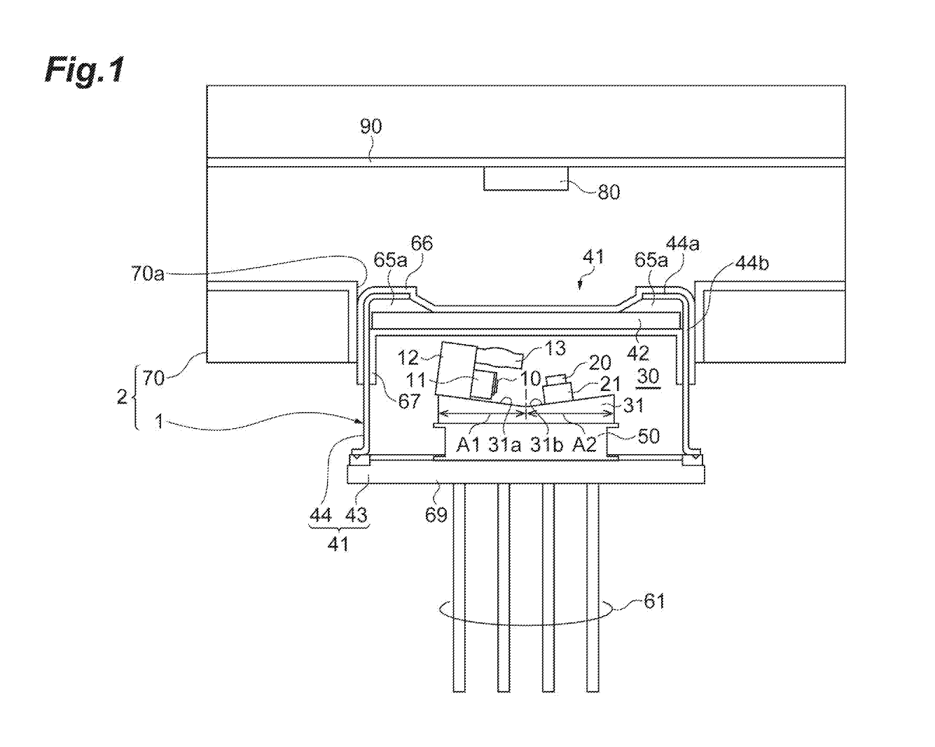

FIG. 1 is a schematic view showing a detecting apparatus including an optical module according to the present embodiment. A detecting apparatus 2 includes an optical module 1 and a holder 70. The optical module 1 includes a light emitting semiconductor device 10, a photodetector 20, and a container 30. The light emitting semiconductor device 10 generates infrared light in mid-wavelengths (specifically, 3 to 6 micrometers) and long-wavelengths (specifically, 6 to 11 micrometers). The photodetector 20 detects light which is generated by the light emitting semiconductor device 10.

The photodetector 20 can detect light in mid-wavelength and long-wavelength infrared ranges. The container 30 includes a supporting member 31 and a package 41. The supporting member 31 has a principal surface with a first area A1 and a second area A2 different from the first area A1. The supporting member 31 supports the light emitting semiconductor device 10 on the first area A1 and supports the photodetector 20 on the second area A2. The package 41 includes an optical window 42, and the optical window 42 has a transmittance of light in mid-wavelength and long-wavelength infrared regions. The package 41 supports the supporting member 31 such that the photodetector 20 on the second area A2 receives a light beam passing through the optical window 42, and the light emitting semiconductor device 10 on the first area A1 emits a light beam to the optical window 42 outward. The optical module 1 can emit light, passing through the optical window 42 outward, with the light emitting semiconductor device 10 and receive light, passing through the optical window 42, with the photodetector 20.

The single package 41 contains the light emitting semiconductor device 10 and the photodetector 20 arranged in the optical module 1, which allows the light emitting semiconductor device 10 to emit light toward the optical window 42 and allows the photodetector 20 to receive light from the optical window 42. The package 41 supports the light emitting semiconductor device 10 in the first area A1 and supports the photodetector 20 in the second area A2. The alignment of the optical module 1 with the detecting apparatus 2 makes both the light emitting semiconductor device 10 and the photodetector 20 optically aligned with the detecting apparatus 2. The single package 2 containing both the light emitting semiconductor device 10 and the photodetector 20 therein allows the light emitting semiconductor device 10 and the photodetector 20 to operate in a common operating environment. Providing the photodetector 20 and the light emitting semiconductor device 10 with the common operating environment can make the optical module 1 small in size.

The light emitting semiconductor device 10 includes, for instance, a quantum cascade laser or an inter-band cascade laser.

The quantum cascade laser can generate light of a wavelength in the range of 3 to 11 micrometers.

The photodetector 20 includes, for instance one of an HgCdTe device, an InSb device, a sensor device of an InAs/GaSb superlattice, a thermopile device, and a collector sensor. The HgCdTe device, the InAs/GaSb-superlattice sensor device, the thermopile device, and the collector sensor each can detect light of a wavelength in a range of 3 to 15 micrometers. The InSb device can detect light of a wavelength in a range of 3 to 6 micrometers.

The optical window 42 includes, for instance at least one of Ge, ZnSe, ZnS, Si, CaF₂, BaF₂, sapphire, diamond and chalcogenide glass. The optical window 42 including a low reflection coating and material selected from the above in accordance with desired wavelengths is transmissive to light of the wavelength in a range of 3 to 14 micrometers.

The supporting member 31 mounts a first sub-mount 11, and the first sub-mount 11 mounts the light emitting semiconductor device 10. The supporting member 31 also mounts a second sub-mount 21, and the second sub-mount 21 mounts the photodetector 20. The supporting member 31 includes, for instance, CuW, Cu, CuMo, AlN, and SiC.

The container 30 further includes a temperature controlling device 50. The temperature controlling device 50 mounts both the light emitting semiconductor device 10 and the photodetector 20. The temperature controlling device 50 can control the common operating environment for the light emitting semiconductor device 10 and the photodetector 20. The temperature controlling device 50 includes, for instance a Peltier device. Specifically, the temperature controlling device 50 mounts the supporting member 31, allowing temperature-controlling of the light emitting semiconductor device 10 and the photodetector 20. The package 41 mounts the temperature controlling device 50 to diffuse heat from the temperature controlling device 50, or provide the temperature controlling device 50 with thermal energy.

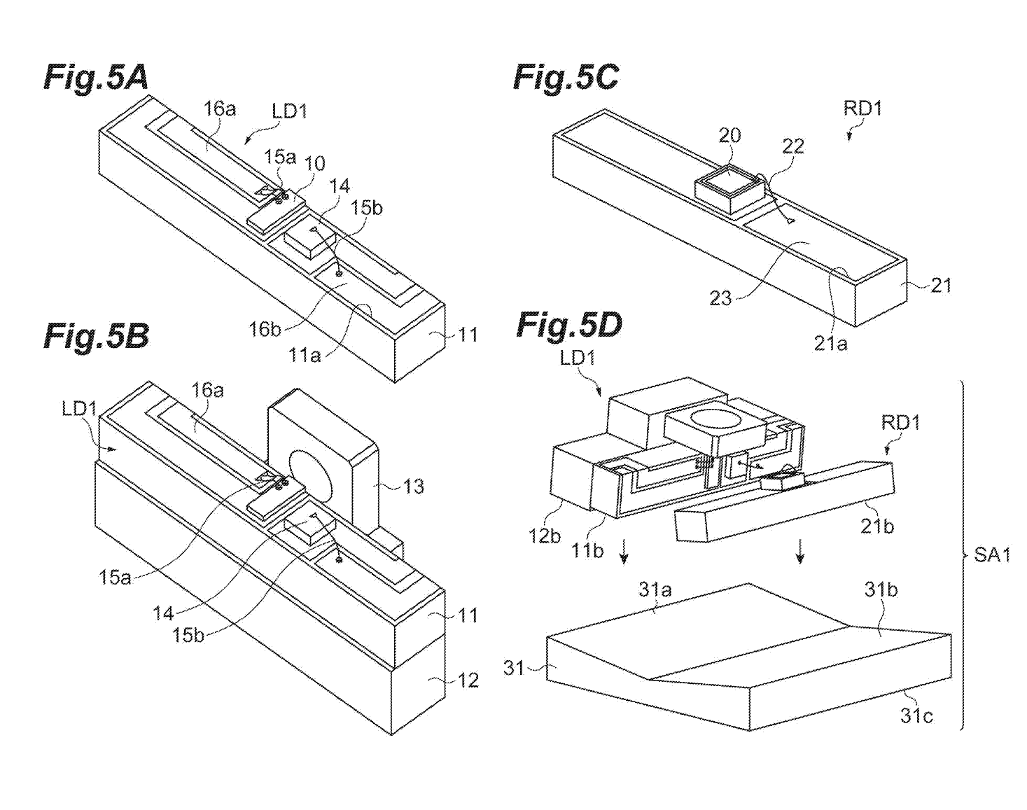

The container 30 includes a temperature detecting device 14, such as a thermistor or a thermal photodiode, (refer to FIGS. 5A and 5B). The temperature detecting device 14 is disposed in the container 30 and is effective in maintaining the common operating environment in which the light emitting semiconductor device 10 and the photodetector 20 operate. The temperature detecting device 14 can be mounted on the supporting member 31 or the temperature controlling device 50. Specifically, the temperature detecting device 14 can be mounted on an upper face 11a of the first sub-mount 11, and can monitor the temperature of the light emitting semiconductor device 10.

The package 41 includes a stein 43 and a cap 44. The stein includes multiple electrical terminals 61, which may be supported by a stein base 69 of the stein 43, and the electrical terminals 61 pass through the stein base 69. A terminal of the electrical terminals 61 are electrically connected to the devices, such as the light emitting semiconductor device 10, the temperature detecting device 14, and the photodetector 20 in the package 41. The cap 44 includes an upper wall 44a and a side wall 44b, and the optical window 42 is supported by, for instance the upper wall 44a. The stein base 69 includes, for instance CuW, Cu, and CuMo, and the cap 44 includes, for instance KOVAR coated with plated Ni or FeNi alloy coated with plated Ni.

The container 30 may have an outer protecting film 66 disposed on the outside of the cap 44. The outer protecting film 66 can cover the upper wall 44a of the cap 44, if needed, the side wall 44b, and can prevent a target gas from degrading the cap 44. The outer protecting film 66 includes, for instance, Diamond like Carbon. Diamond like Carbon has corrosion-resistance to acids and alkalies, which may be involved in an environmental gas. The outer protecting film 66 is made of material, such as a YbS family material, a MgF family material, a YF family material, a BiO family material, and an antireflection film including an inorganic materials, such as Ge and ZnS. The container 30 may have an antireflection film 67 disposed on an inner face of the cap 44. The antireflection film 67 can be made of material, such as inorganic materials for the outer protecting film of the cap, specifically, a YbS family material, a MgF family material, a YF family material and a BiO family material, and materials, such as Ge and ZnS. The antireflection film 67 is disposed so as to cover the edge of the optical window 42. The addition of the antireflection film 67 to the optical window 42 can reduce loss of light which enters the optical module 1 through the optical window 42 and goes out of the optical module 1 through the optical window 42, enabling the present apparatus to make a high-accuracy measurement.

The container 30 includes a supporting base 12, and an optical lens 13 in addition to the first sub-mount 11 and the second sub-mount 21. The supporting base 12 and the second sub-mount 21 are fixed to the principal surface of the supporting member 31. The light emitting semiconductor device 10 is mounted on the first sub-mount 11, and the first sub-mount 11 is mounted on the supporting base 12. The first sub-mount 11 includes ceramics, such as AlN, SiC Al—SiC, and Si—SiC, or diamond. The optical lens 13 is disposed on the supporting base 12, and optically couples the emitting face of the light emitting semiconductor device 10 with the optical window 42. The optical lens 13 may include, for instance, a collimating lens or a focusing lens. The photodetector 20 is mounted on the second sub-mount 21. The second sub-mount 21 may include ceramics, such as AlN, Al₂O₃, SiC, Al—SiC, and Si—SiC, or diamond.

Referring to FIG. 1, a description will be given of the detecting apparatus 2. The detecting apparatus 2 includes the optical module 1, a holder 70, and a reflection member 80. The holder 70 supports the optical module 1 and the reflection member 80. The holder 70 has a holding member 70a, which holds the optical module 1. The holding member 70a supports the optical module 1, which makes contact with the outer surface thereof, and specifically holds the cap of the optical module 1 so as to seal a measurement room with the optical module 1. The holder 70 supports the reflection member 80 so as to separate the reflection member apart from the optical module 1. The reflection member 80 includes one or more reflection faces which can reflects mid-wavelength and long-wavelength infrared light from the light emitting semiconductor device 10. The reflection member 80 is optically coupled to the light emitting semiconductor device 10 through the optical window 42 of the optical module 1, and is optically coupled to the photodetector 20 through the optical window 42 of the optical module 1. These optical couplings provide an optical path from the light emitting semiconductor device 10 to the photodetector 20 through the reflection member 80, and the light emitting semiconductor device emits light toward the reflection member 80 that reflects the incident light toward the photodetector. The container 30 of the optical module 1 aligns the light emitting semiconductor device 10 and the photodetector 20 with each other such that light from the light emitting semiconductor device 10 travels to pass through the reflection member 80 twice finally to the photodetector 20.

The holder 70 has a measurement room 90. The measurement room 90 has a longitudinal path allowing a gaseous target material to flow therethrough and allowing the gaseous target material to be irradiated with the laser beam for the optical measurement. The detecting apparatus 2 can conduct an optical measurement by using mid-wavelength infrared light or long-wavelength infrared light from the light emitting semiconductor device 10. The detecting apparatus 2 identifies a kind of gas or a concentration of the gas, such as CO, CO₂, CH₄, NO, NO₂, or SO₂. The measurement room 90 is formed by a chamber including corrosion-resistant material, such as, silica glass, Diamond like Carbon, SUS metal coated with a corrosion-resistant material, for instance a fluorine-based resin. In one embodiment, the measurement room 90 includes a flow channel allowing gas to flow. The flow channel has a cross-section area of, for instance, 10 to 100 mm². The reflection member 80 is disposed on an inner side face which defines the measurement room 90. The reflection member 80 includes, for instance, a gold film, and can reflect mid-wavelength or long-wavelength infrared light.

The light emitting semiconductor device 10 is supported by the supporting member 31 such that the light emitting semiconductor device 10 emits incident light to the reflection member 80 outside of the optical module 1 and the reflection member 80 produces returning light, which travels to the photodetector 20, from the incident light by reflection thereof. The photodetector 20 is supported by a supporting member 31 such that the photodetector 20 receives the returning light from the reflection member 80 outside of the optical module 1, and the reflection member 80 produces the returning light from the incident light from the light emitting semiconductor device 10 by reflection thereof.

### EXAMPLE 1

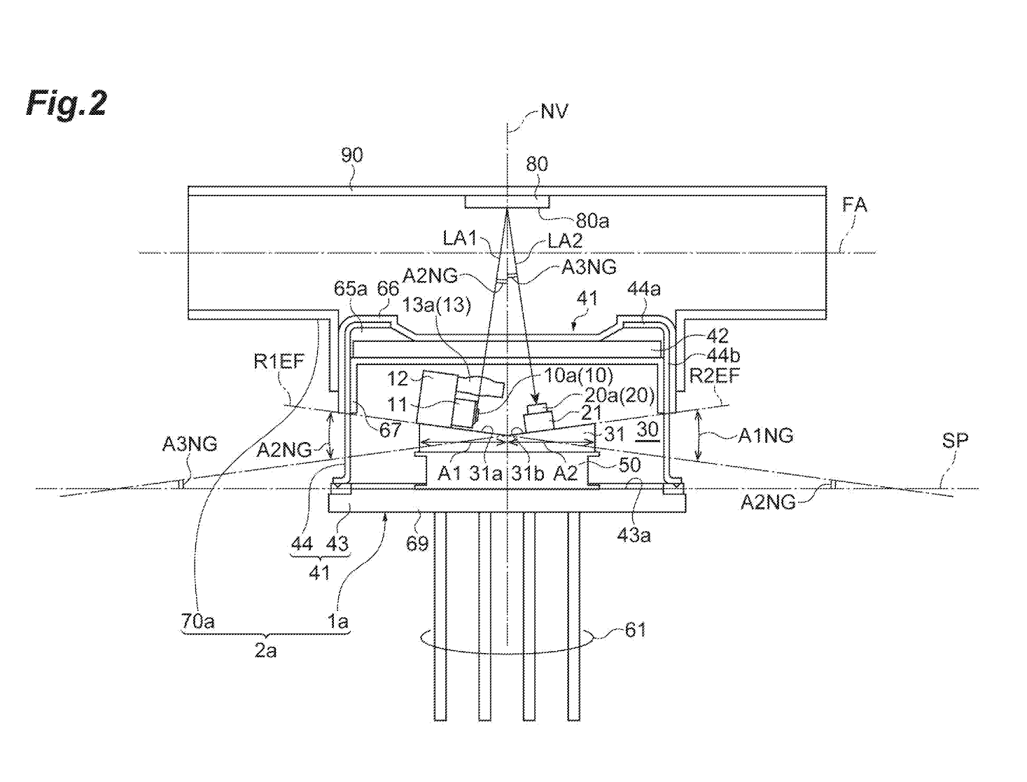

FIG. 2 is a schematic view showing a detecting apparatus according to Example 1. In an optical module 1A and a detecting apparatus 2A, the optical lens 13 includes a collimate lens 13a, and the collimate lens 13a is disposed between the light emitting semiconductor device 10 and the optical window 42. The collimate lens 13a is positioned to the light emitting semiconductor device 10 on the supporting base 12 so as to provide a collimated light beam to the optical window 42.

The reflection member 80 includes a single reflection face 80a, and the single reflection face 80a may be made of, for instance, gold, silver, or aluminum. The light emitting semiconductor device 10 produce an outgoing light beam LA1 to the reflection member 80 through the optical window 42 and the flow channel, and the light beam LA1 is reflected by the reflection face 80a of the reflection member 80 to produce a reflected light beam LA2. The reflected light beam LA2 passes through the flow channel and the optical window 42 to the photodetector 20.

The principal surface of the supporting member 31 includes a first face 31a and a second face 31b. The first and second faces 31a and 31b are positioned to the first and second areas A1 and A2, respectively. The first and second faces 31a and 31b extend along a first reference plane R1EF and a second reference plane R2EF, respectively. The first reference plane R1EF is inclined with the second reference plane R2EF at an angle of more than zero to less than 90 degrees. Specifically, the first reference plane R1EF is inclined with the second reference plane R2EF at a first angle A1NG. The first face 31a and the second face 31b are, for instance, inclined with each other at an angle of 2 to 25 degrees. The first face 31a and the second face 31b are slightly inclined inward to form a shallow groove. In this example, the stein 43 mounts a Peltier device on the inner area of the upper face 43a, and supports the cap 44 on the outer area of the upper face 43a. The inner area of the stein 43 includes a mounting face extending along a reference plane SP. The first reference plane R1EF is inclined with the reference plane SP at a second angle A2NG, and the second reference plane R2EF is inclined with the reference plane SP at a third angle A3NG. The second angle A2NG determines, with respect to an axis NV along which the stein 43 and cap 44 are arranged, an inclination of an axis along which the light emitting semiconductor device 10 emits light. The third angle A3NG determines an inclination of an axis normal to a light receiving face of the photodetector 20 with respect to the alignment axis NV. These inclinations allow the single reflection face 80a to reflect light outgoing along the axis inclined to the alignment axis NV in accordance with the law of reflection to produce a reflected incoming light beam, and the incoming light beam propagates along the optical axis inclined to the alignment axis NV.

The measurement room 90 allows gas to flow along the flow channel axis FA in measuring the gas. In Example 1, a quantum cascade laser 10a of the light emitting semiconductor device 10 emits a light beam, and this light beam is collimated with the lens, and the collimated light beam obliquely passes through the measurement room 90 twice through which the gas flows. The passing of the gas through the measurement room 90 allows gaseous material therein to absorb light at one or more optical wavelengths each inherent to the gaseous component in the gas, and produces transmitted light with an optical absorption spectrum, and the transmitted light is incident on a HgCdTe device of the photodetector 20, which detects an intensity of the remaining light at the absorption wavelength. The detection data from the HgCdTe device identify the kind and volume of the component contained in the gas.

### EXAMPLE 2

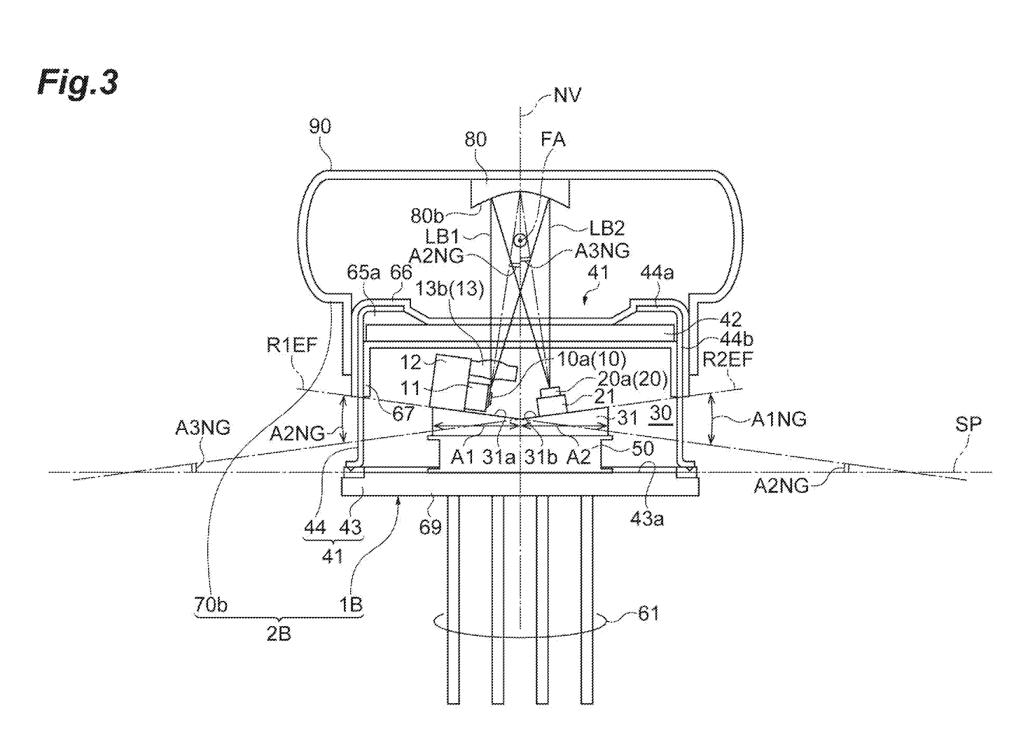

FIG. 3 is a schematic view showing a detecting apparatus according to Example 2. In an optical module 1B and a detecting apparatus 2B, the optical lens 13 includes the collimate lens 13b, and the collimate lens 13b is disposed between the light emitting semiconductor device 10 and the optical window 42. The collimate lens 13b is positioned to the light emitting semiconductor device 10 on the supporting base 12 so as to illuminate the optical window 42 with a diffused light beam. The reflection member 80 includes a single concave reflection face 80b, and the concave reflection face 80b includes, for instance, gold, silver, or aluminum. The light emitting semiconductor device 10 emits a light beam LB1, which travels through the optical window 42 and the flow channel to the concave reflection face 80b. The concave reflection face 80b of the reflection member 80 produces a reflected light beam LB2 in accordance with the low of reflection, and this light beam from the concave reflection face 80b passes through the flow channel and the optical window 42 to finally reach the photodetector 20.

The principal surface of the supporting member 31 includes the first face 31a and the second face 31b. The first and second faces 31a and 31b are aligned with the first and second areas A1 and A2, respectively. The first and second faces 31a and 31b extend along the first and second reference planes R1EF and R2EF, respectively. The first reference plane R1EF is inclined with the second reference plane R2EF at an angle of more than zero to less than 90 degrees. Specifically, the first reference plane R1EF is inclined with the second reference plane R2EF at the first angle A1NG. The first and second faces 31a and 31b are inclined with each other, for instance, at an angle of 2 to 25 degrees. The first and second faces 31a and 31b are slightly inclined inward to from a shallow groove. In one example, the stein 43 mounts a Peltier device on the inner area of the upper face 43a, and supports the cap 44 on the outer area of the upper face 43a. The inner area of the stein 43 includes a mounting face spreading along a reference plane SP. The first reference plane R1EF is inclined with the reference plane SP at the second angle A2NG, and the second reference plane R2EF is inclined with the reference plane SP at the third angle A3NG. The second angle A2NG determines, with respect to an alignment axis NV along which the stein 43 and cap 44 are arranged, an inclination of an axis along which the light emitting semiconductor device 10 emit light. The third angle A3NG determines an inclination of an axis normal to the light receiving face of the photodetector 20 with respect to the alignment axis NV. These inclinations allow the single concave reflection face 80b to reflect light outgoing along the axis inclined to the alignment axis NV in accordance with the law of reflection to produce a reflected light beam, the optical axis of which is inclined with respect to the alignment axis NV.

The measurement room 90 allows the gas to flow along the flow channel axis FA in measuring the gas. In Example 2, the quantum cascade laser 10a emits a diffused light beam, and the diffused light beam obliquely passes through the gas in the measurement room 90 twice through which the gas flows. The passing of the gas through the measurement room 90 allows gaseous material to absorb light at one or more optical wavelengths each inherent to the gaseous component in the gas, and produces transmitted light with an optical absorption spectrum. The transmitted light is incident on the photodetector 20, which detects an intensity of the remaining light at the absorption wavelength. The detection data from the HgCdTe device identify the kind and volume of the component contained in the gas.

### EXAMPLE 3

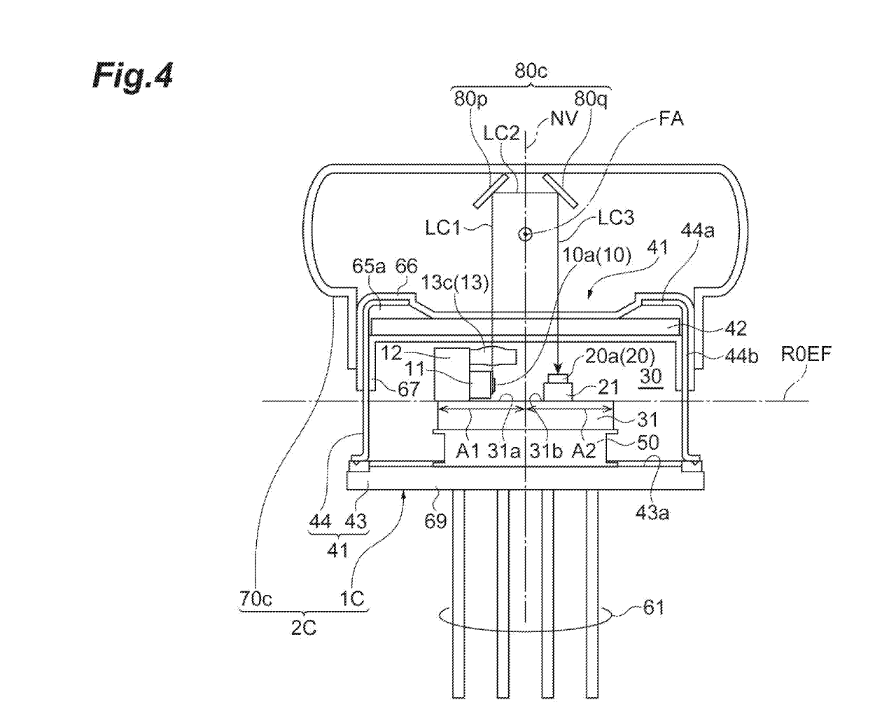

FIG. 4 is a schematic view showing a detecting apparatus according to Example 3. In an optical module 1C and a detecting apparatus 2C, the optical lens 13 includes a collimate lens 13c, and the collimate lens 13c is disposed between the light emitting semiconductor device 10 and the optical window 42. The collimate lens 13c is positioned to the light emitting semiconductor device 10 on the supporting base 12 so as to provide the optical window 42 with a collimated light beam. The reflection member 80 includes multiple flat reflection faces 80p and 80q, and the flat reflection faces 80p and 80q each include, for instance gold, silver, or aluminum. The light emitting semiconductor device 10 emits an outgoing light beam LC1, and this outgoing light beam passes through the optical window 42 and the flow channel to the reflection member 80 to the flat reflection faces 80p of the reflection member 80. The flat reflection faces 80p of the reflection member 80 produce a reflected light beam LC2 in accordance with the low of reflection. The reflected light beam LC2 propagate from the flat reflection faces 80p to the flat reflection face 80q. The reflection flat face 80q reflects the reflected light beam LC2 to produce a returning light beam LC3 in accordance with the low of reflection. The returning light beam LC3 travels through the flow channel and the optical window 42 to finally reach the photodetector 20.

The principal surface of the supporting member 31 extends along a reference flat plane R0EF. The supporting base 12 and the second sub-mount 21 are mounted on the principle surface of the supporting member 31. The outgoing light beam LC1 propagates from the light emitting semiconductor device 10 in a substantially parallel to the alignment axis NV. This light beam is reflected twice by the flat reflection faces 80p and 80q, and the twice-reflected light returns in a direction substantially parallel to the alignment axis NV.

The measurement room 90 allows gas to flow along the flow channel axis FA in measuring the gas. In Example 3, a quantum cascade laser 10a of the light emitting semiconductor device 10 emits a light beam, and this light beam is collimated with the lens, and the collimated light beam obliquely passes through the measurement room 90 twice through which the gas flows. The passing of the gas through the measurement room 90 allows gaseous material to absorb light at one or more optical wavelengths each inherent to the gaseous component in the gas, and produces transmitted light having an optical absorption spectrum, and the transmitted light is incident on the photodetector 20, which detects an intensity of the remaining light at the absorption wavelength. The detection data from the photodetector 20 identify the kind and volume of the component contained in the gas.

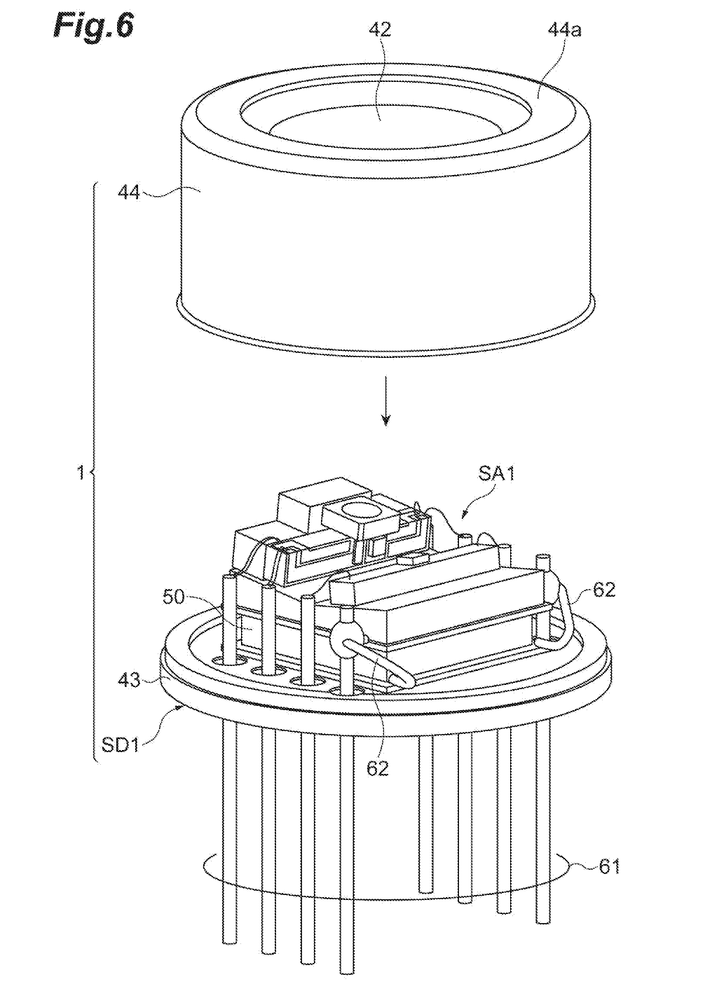

Referring to FIGS. 5A, 5B, 5C, 5D, and 6, a description will be given of a method for fabricating the optical module. The description is beneficial to understand a specific structure of the optical module 1. When possible, the same portions will be denoted by the same reference numerals used in FIG. 1.

As shown in FIG. 5A, the first sub-mount 11 is prepared. The light emitting semiconductor device 10 is die-bonded to the upper face 11 a of the first sub-mount 11 with a solder of Au-20Sn, and the temperature sensitive device 14, such as a thermistor, is die-bonded to the upper face 11 a of the first sub-mount 11 with the solder of Au-20Sn. The light emitting semiconductor device 10 is connected to an interconnection substrate 16a on the upper face 11a with a wire conductor 15a, and the temperature sensitive device 14 is connected to an interconnection substrate 16b on the upper face 11 a of the first sub-mount 11 with a wire conductor 15b. These processes produce a light emission assembly LD1.

As shown in FIG. 5B, the light emission assembly LD1 is mounted on the supporting base 12, and the optical lens 13 is fixed thereto with an epoxy-based adhesive. If necessary, the optical lens 13 is positioned to be optically coupled to the light emission face of the light emitting semiconductor device 10. These processes produce an assembly including the supporting base 12, the light emission assembly LD1, and the optical lens 13.

As shown in FIG. 5C, the second sub-mount 21 is prepared. The photodetector 20 is die-bonded to the upper face 21a of the second sub-mount 21 with a solder of Au-20Sn. The photodetector 20 is connected to an interconnection substrate 23 on the upper face 21a with a wire conductor 22. These processes produce a light receiving assembly RD1.

As shown in FIG. 5D, the light emission assembly LD1 and the light receiving assembly RD1 are fixed to the first and second faces 31a and 31b of the supporting member 31, respectively, with solders of Sg—Ag—Cu. The light emission assembly LD1 and the light receiving assembly RD1 are arranged on the first and second faces 31a and 31b, respectively, such that the supporting member 31 is in contact with a back side 12b of the supporting base 12 and a back side 21b of the second sub-mount 21. This arrangement can orient the light emission assembly LD1 and the light receiving assembly RD1 in accordance with the structure of the reflection member 80 in the detecting apparatus 2 to which the optical module 1 is attached. The orientations of the light emission assembly LD1 and the light receiving assembly RD1 are associated with the inclinations of the first and second faces 31a and 31b of the supporting member 31. The supporting member 31 and the assemblies LD1 and RD1 positioned thereon allows light from the light emitting semiconductor device 10 in the light emission assembly LD1 to return to the photodetector 20 in the light receiving assembly RD1 through the reflection member 80 disposed outside of the optical module 1. The above processes produce an optical subassembly SA1.

As shown in FIG. 6, the optical subassembly SA1 is fixed to the temperature controlling device 50 with an Ag-epoxy paste, and after the fixation, the temperature controlling device 50 is fixed to the stein 43. The light submodule SD1 is connected to the electrical terminals 61 of the stein 43 with wire conductors 62. The cap is prepared which has the optical window 42, and the optical window 42 is fixed to the upper wall 44a thereof with, for instance, a low-melting point glass and an epoxy-based adhesive. The cap 44 is fixed to the stein 43, for instance, by resistance welding. The above processes bring an optical module 1 to completion.

As seen from the above description, the present embodiments provide an optical module allowing the alignment of the optical module with a detecting apparatus to make the light source and the detector therein aligned with the detecting apparatus and making the difference between operating environments of the light source and the detector reduced. The present embodiments also provide a detecting apparatus including the optical module.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. An optical module comprising:
a light emitting semiconductor device producing light in a middle and long wavelength infrared range;
a photodetector sensitive to middle and long wavelength infrared light; and
a container including a supporting member and a package, the supporting member having a first area and a second area different from the first area,
the package including an optical window transmissive to middle and long wavelength infrared light, the light emitting semiconductor device being disposed on the first area, the photodetector being disposed on the second area, and the package supporting the supporting member so as to allow the light emitting semiconductor device to emit the light to the optical window and allow the photodetector to receive light through the optical window.

2. The optical module according to claim 1, wherein the optical window includes at least one of Ge, ZnSe, ZnS, Si, CaF₂, BaF₂, sapphire, diamond, or chalcogenide glass.

3. The optical module according to claim 1, wherein the photodetector includes one of an HgCdTe device, a sensor device having an InAs/GaSb superlattice, and a thermopile device.

4. The optical module according to claim 1, wherein the light emitting semiconductor device includes a quantum cascade laser.

5. The optical module according to claim 1,
further comprising a temperature controlling device mounting the photodetector and the light emitting semiconductor device, the package including a stein and a cap, the cap having the optical window, and the stein mounting the temperature controlling device.

6. The optical module according to claim 1,
wherein the photodetector is supported by the supporting member to receive returning light from a reflection member outside of the optical module, and the reflection member reflects the light from the light emitting semiconductor device to produce returning light.

7. The optical module according to claim 1,
wherein the light emitting semiconductor device is supported by the supporting member to provide the photodetector with returning light from a reflection member outside of the optical module, and the reflection member reflects light from the light emitting semiconductor device to form returning light.

8. A detecting apparatus comprising:
an optical module including;
a light emitting semiconductor device producing light in a middle and long wavelength infrared range;
a photodetector sensitive to middle and long wavelength infrared light; and
a container including a supporting member and a package,
the supporting member having a first area and a second area different from the first area,
the package including an optical window transmissive to middle and long wavelength infrared light, the light emitting semiconductor device being disposed on the first area, the photodetector being disposed on the second area, and the package supporting the supporting member so as to allow the light emitting semiconductor device to emit the light to the optical window and allow the photodetector to receive light through the optical window;
a holder including a holding portion holding the optical module; and
a reflecting member being supported by the holder apart from the supporting member, the reflecting member reflecting the light from the light emitting semiconductor device.
